(19) United States
(12) Patent Application Publication
(10) Pub. No.: US 2010/0222918 A1
(43) Pub. Date: Sep. 2, 2010

(54) TRANSFER DEVICE AND TRANSFER METHOD

(75) Inventors: Hideaki Nonaka, Tokyo (JP); Kan Nakata, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: LINTEC CORPORATION, Tokyo (JP)

(21) Appl. No.: 12/160,516

(22) PCT Filed: Jan. 22, 2007
(86) PCT No.: PCT/JP2007/050899

§ 371 Date: Jul. 10, 2008

(30) Foreign Application Priority Data
Feb. 20, 2006 (JP) 2006-042110

(51) Int. Cl. H01L 21/677; B25J 13/00

(52) U.S. Cl. 700/228; 700/245; 901/2; 901/15; 901/40

(57) ABSTRACT

A conveyance device (10) constructed from a multijoint robot having first to sixth arms (15A-15F) that are each numerically controlled. A suction arm (12) for sucking and holding a semiconductor wafer (W) is provided on the free end side of the conveyance device (10). The suction arm (12) has a suction section (12C) on the forward end side of the arm and is mounted so as to be movable in three perpendicular axes (X, Y, Z axes) through the arms (15A-15F) and so as to be rotatable in the direction tilting relative to an imaginary plane (S). Accordingly, even if the semiconductor wafer (W) is tilted relative to the imaginary plane (S), the suction section (12C) can be brought to intimate contact with the wafer (W) by changing the angle of the suction arm (12).

### TECHNICAL FIELD

The present invention relates to a transfer device and a transfer method, and more particularly to a transfer device and a transfer method which can assuredly suck, hold and transfer a plate-like object such as a semiconductor wafer (which will be simply referred to as a “wafer” hereinafter) put on an upper surface of a table or the like even in a state where a surface of the plate-like object is inclined with respect to a virtual flat plane (e.g., a horizontal plane) when transferring the plate-like object.

### BACKGROUND ART

A wafer processing step includes various kinds of steps such as a rear surface grinding step of the wafer or a mounting step of the wafer with respect to a ring frame. In case of executing processing in each step, a transfer device provided with holding means for sucking and holding the wafer is used to transfer it between tables, wafer stockers or the like (see, e.g., Patent Document 1).

The transfer device described in the above-mentioned Patent Document is, as schematically shown in FIG. 4, provided with a robot body 50, an elevating body 51 supported by the robot body 50 to allow its elevating movement, a proximal arm 52 supported by the elevating body so as to be rotatable within a horizontal plane, a distal arm 54 connected with the proximal arm 52 through a middle arm 53 so as to be rotatable within the horizontal plane and a suction arm 56 disposed on a free end side of the distal arm 54, whereby a non-illustrated sucking portion provided to the suction arm 56 sucks and holds a wafer W supported on a first table 60, the wafer W can be transferred to and put on a second table 61 from a first table 60 or vice versa.

[Patent Document 1] Japanese Patent Application Laid-open No. 2005-123595

### DISCLOSURE OF INVENTION

### Problem to be Solved by the Invention

However, the suction arm 56 in the transfer device disclosed in Patent Document 1 only moves (rotates) in a vertical direction involved by upward and downward movements of the elevating body 51 and a horizontal direction along which the respective arms 52 to 54 swivel within the horizontal plane, and the suction arm 56 cannot be inclined with respect to the horizontal plane.

Therefore, even if a reference (a leveling reference) is provided in this device to set the transfer device, the leveling reference may be slightly out of alignment because there is an individual difference when the device is combined with the other device (see θ in FIG. 4). In such a case, since the suction arm cannot suck the wafer W of the other device, the reference of the device or the other device must be again provided in accordance with inclination of one of these devices at the time of setting, thereby producing an inconvenience, i.e., involving a very troublesome and extensive work.

### Object of the Invention

In view of the above-described inconvenience, it is an object of the present invention to provide a transfer device and a transfer method which can assuredly suck, hold and carry a plate-like object such as a wafer even in a state where the plate-like object is inclined with respect to a virtual flat plane.

### Means for Solving the Problem

To achieve the object, the present invention adopts an arrangement in a transfer device, which comprises a multi-joint type robot provided with a plurality of joints each of which is subjected to numerical control,

wherein holding means for holding a plate-like object is provided on a free end side of the robot, and the holding means is provided to be movable in directions of three axes perpendicular to each other, inclined with respect to a virtual flat plane at a predetermined angle and provided to allow contact with the plate-like object.

Further, the present invention adopts an arrangement in a transfer device which comprises a multi-joint type robot provided with a plurality of joints each of which is subjected to numerical control,

wherein a suction arm which sucks and holds a semiconductor wafer is provided on a free end side of the robot, and the suction arm is provided to be movable in directions of three axes perpendicular to each other, inclined with respect to a virtual flat plane at a predetermined angle and provided to allow contact with the semiconductor wafer, thereby bringing a sucking portion into contact with the semiconductor wafer.

Furthermore, the present invention adopts a transfer method for transferring a plate-like object through a transfer device in which a suction arm which sucks and holds the plate-like object is provided on a free end side of a multi-joint type robot to be movable in directions of three axes perpendicular to each other, the multi-joint type robot including a plurality of joints each of which is subjected to numerical control,

the transfer method comprising:

inclining the suction arm in accordance with inclination of the plate-like object and bringing a sucking portion of the suction arm into contact with a surface of the plate-like object when the plate-like object is inclined with respect to a virtual flat plane in case of sucking the plate-like object by the suction arm; and

subsequently transferring the plate-like object in a state where the plate-like object is sucked by the sucking portion.

### Effect of the Invention

According to the present invention, since there is adopted an arrangement in which the holding means consisting of the suction arm or the like can move in directions of three axes perpendicular to each other and a direction or an attitude inclined with respect to the virtual flat plane, even if the plate-like object such as a wafer is supported on a inclined table for example, the sucking portion of the suction arm can displace an angle or displace an attitude to allow holding so as to come into close contact with a surface of the plate-like object, thereby assuredly sucking and transferring the plate-like object.

Moreover, in a case where the plate-like object is transferred in a plurality of steps, even if a leveling accuracy of each table is not maintained, it is possible to cope with this matter by controlling the holding means to adjust an angle corresponding to the inclination, and hence a large-scale work of setting a reference with respect to the other device becomes no longer necessary.

### BRIEF DESCRIPTION OF DRAWINGS

FIG. 1 is a schematic perspective view showing a transfer device according to the embodiment;

FIG. 2 is a front view of the transfer device;

FIG. 3 is an explanatory view of a function at the time of a sucking operation by a suction arm; and

FIG. 4 is a front view of a transfer device showing a conventional structure.

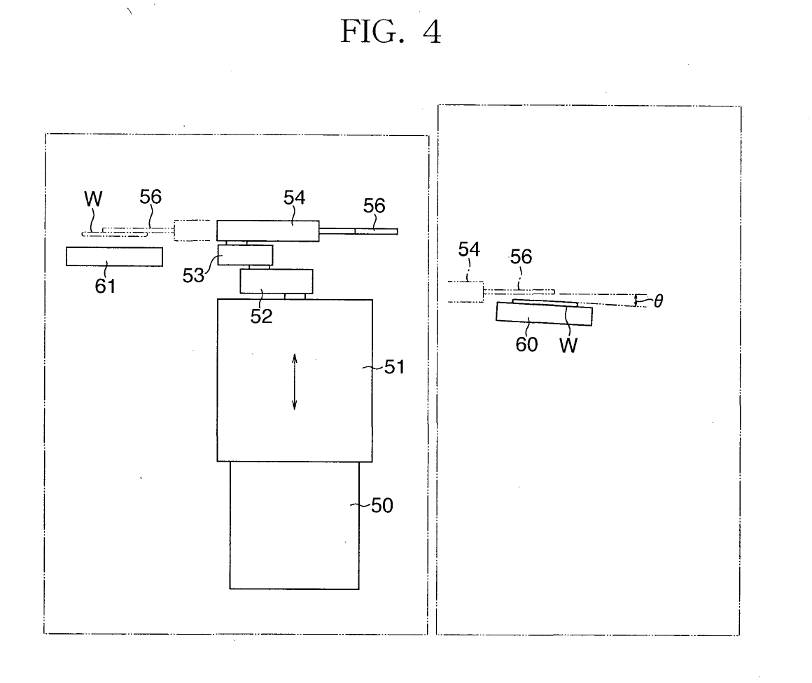

### DESCRIPTION OF NUMERAL REFERENCE

10 Transfer Device
11 Robot Body
12 Suction Arm (holding means)
12C Sucking Portion
15A to 15F First to Sixth Arms
S Virtual Flat Plane (horizontal plane)
W Semiconductor Wafer (plate-like object)

### BEST MODES FOR CARRYING OUT THE INVENTION

An embodiment according to the present invention will now be described hereinafter with reference to the drawings.

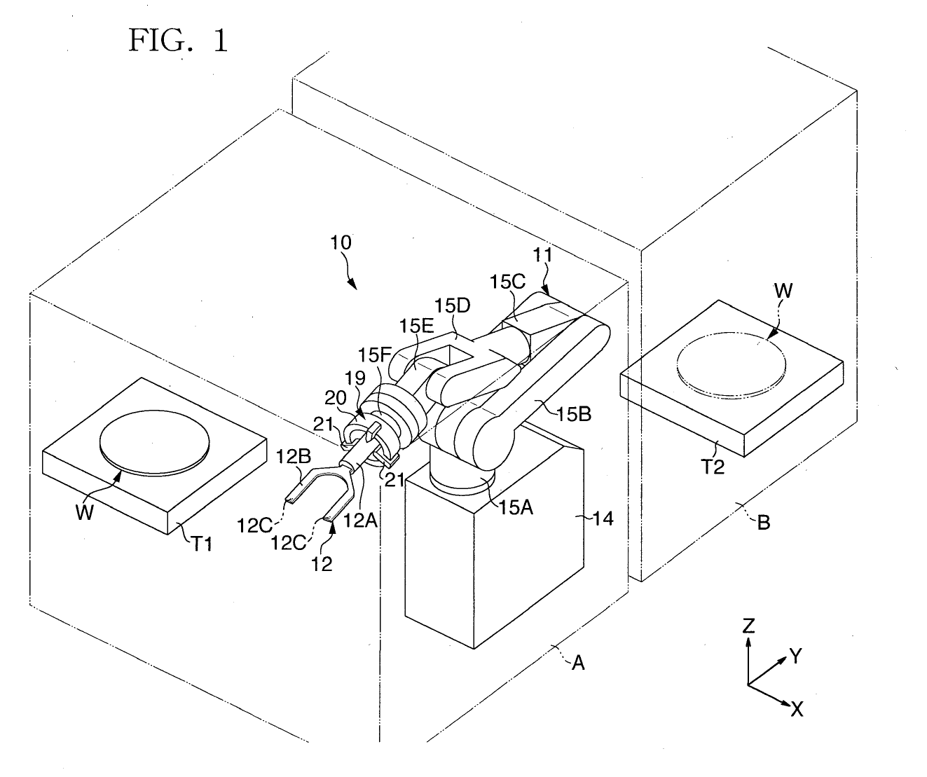

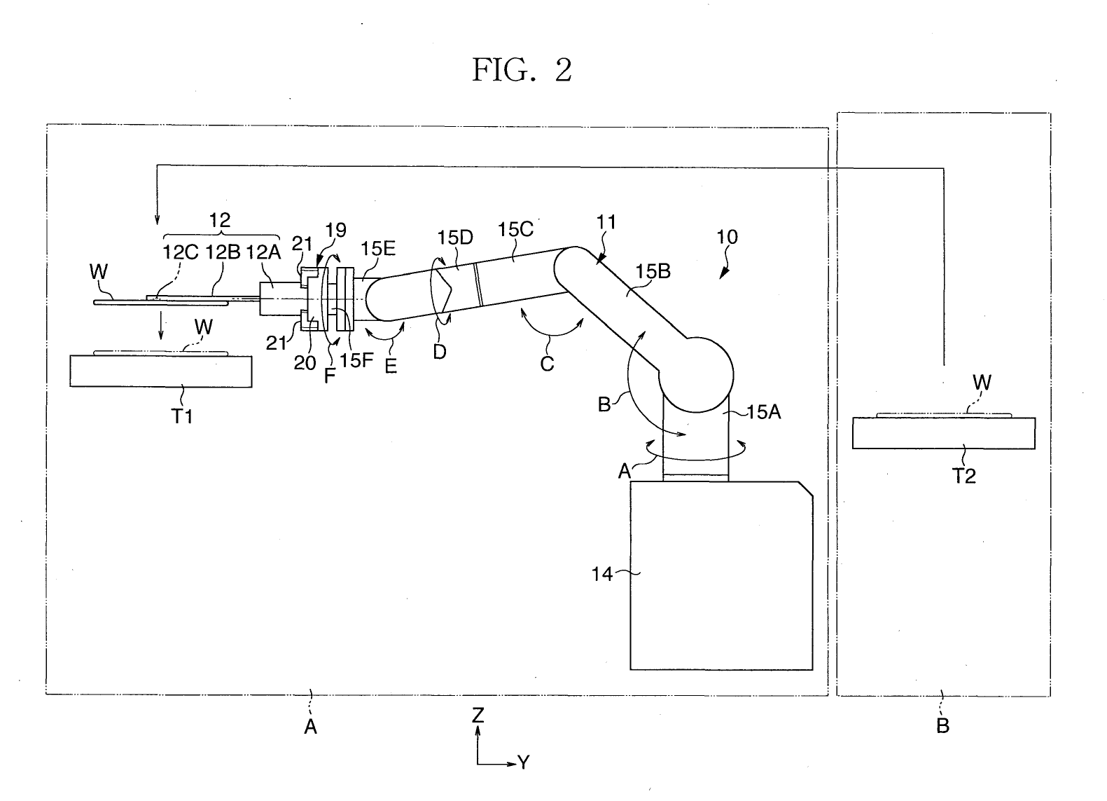

FIG. 1 shows a schematic perspective view in which a transfer device according to the embodiment is applied to a wafer transfer device, and FIG. 2 shows its side view. In these drawings, a transfer device 10 comprises a multi-joint type robot including a plurality of joints, incorporated into a device A provided with a first table T1 for put on a wafer W on an upper surface thereof, and arranged beside a device B incorporated therein with a second table T2.

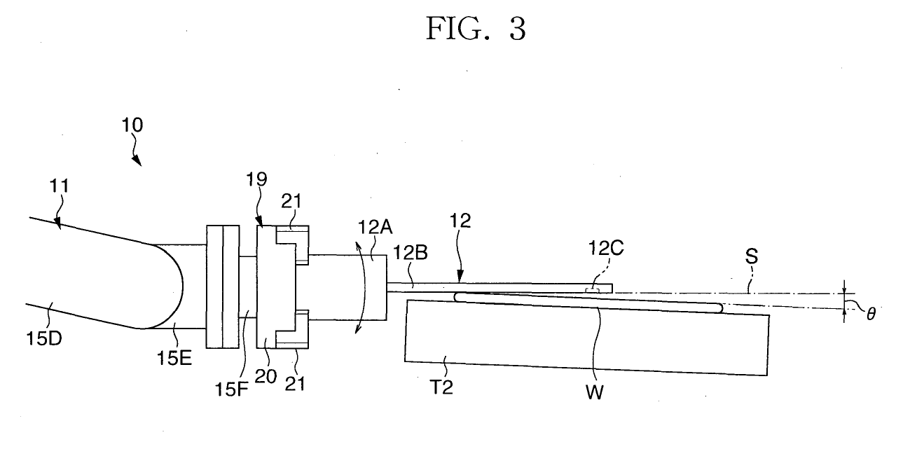

The transfer device 10 includes a robot body 11 and a suction arm 12 as holding means which is supported on a free end side of the robot body 11 and provided to be movable in directions of three axes perpendicular to each other (X, Y and Z axes). The robot body 11 includes a base portion 14, first to sixth arms 15A to 15F which are arranged on an upper surface side of the base portion 14 and form a plurality of joints provided to be rotatable in directions of arrows A to F in FIG. 2, and a tool holding chuck 19 disposed on a distal end side of the sixth arm 15F, i.e., a free end side of the robot body 11. The second, third and fifth arms 15B, 15C and 15E are provided to be rotatable in Y and Z planes in FIG. 2, and the first, fourth and sixth arms 15A, 15D and 15F are provided to be rotatable around their axis. Therefore, the suction arm 12 can move in the directions of the three axes perpendicular to each other, be inclined with respect to a virtual flat plane S (see FIG. 3) and move to, an arbitrary position in a state where it is held by the tool holding chuck 19. The virtual flat plane S in this embodiment is a horizontal plane, and the transfer device 10 is controlled based on numeral control. That is, an amount of movement of each joint with respect to the wafer W is controlled based on each corresponding numerical information, and the amount of movement of each of all the joints is controlled based on a program.

The suction arm 12 includes of a shaft-like arm holder 12A supported by the tool holding chuck 19 and a substantially-Y-shaped arm 12B supported by this arm holder 12A, the arm 12B having a sucking portion 12C on each distal end side thereof. It is to be noted that a plurality of types of, e.g., large and small suction arms 12 are prepared in accordance with a size of the wafer W, they are accommodated in a non-illustrated arm stocker, and a suction arm corresponding to a size of a wafer can be automatically replaced.

The tool holding chuck 19 includes a receiver 20 which has a substantially cylindrical shape and receives the arm holder 12A of the suction arm 12 and three chuck claws 21 which are arranged at positions in a circumferential direction of the receiver 20 at intervals of substantially 120 degrees and fasten and hold the arm holder 12A from the circumferential direction. Each chuck claw 21 is retractable in a radial direction with respect to a center of the receiver 20 by an air pressure.

A function of the embodiment will now be explained. Here, a description will be given as to an example where the wafer W subjected to predetermined processing by a device B is put onto the second table T2 and the wafer W is transferred onto the first table T1 incorporated into a device A.

As shown in FIG. 2, although the device A is set to be adjacent to the device B, parallelism of the first table T1 and the transfer device 10 is accurately adjusted in the device. A, but levelness of the second table T2 is unknown in the device B since the device B has been previously set.

Subsequently, the suction arm 12 is moved closer to the upper side of the second table T2 in the device B by a predetermined movement of each joint of the transfer device 10. Moreover, the sucking portion 12C performs suction to confirm whether the wafer W can be sucked and held.

However, as shown in FIG. 3, when the second table T2 is inclined at an angle θ with respect to the virtual flat plane S, the sucking portion cannot come into contact with the upper surface of the wafer W, whereby the wafer W cannot be sucked and held.

Thus, the transfer device 10 is used to mutually rotate, e.g., the fourth and fifth arms 15D and 15E at a predetermined angle within Y and Z planes in such a manner that suction arm 12 takes an attitude by which the distal end side thereof becomes lower than a proximal end side thereof, and adjust an angle to bring the sucking portion 12C into close contact with the upper surface of the wafer W, thereby performing adjustment to assuredly suck and hold the wafer W. Additionally, data of a position of the suction arm 12 capable of sucking and holding is input to a control device, and thereafter the suction arm 12 moves closer to the wafer W which is put onto the second table T2 and is inclined at the input predetermined angle, thereby coming into contact with and assuredly and automatically sucking and holding the wafer W.

Therefore, according to the embodiment, even in a state where leveling accuracies of the tables T1 and T2 become uneven and the upper surface of the wafer W is thereby inclined with respect to the virtual flat plane S, the wafer W can be sucked and held without adjusting the leveling accuracies of the tables T1 and T2, thus obtaining an effect of enabling transfer of the wafer W in accordance with a preset order.

As described above, although the best arrangement, method and others for carrying out the present invention are disclosed in the above description, the present invention is not restricted thereto.

That is, although the present invention is specifically illustrated and explained as to a specific embodiment, persons skilled in the art can add various modifications to the foregoing embodiment as required in relation to a shape, a position, an arrangement or the like without departing from the technical concept and the scope of the present invention.

For example, although the description has been given as to the operation that the suction arm 12 moves closer to the wafer W put onto the second table T2 and is inclined at the input predetermined angle to come into contact with, suck and hold the wafer W in the foregoing embodiment, the present invention is not restricted thereto, and the suction arm 12 may be inclined at a predetermined angle in advance and then moved closer to and come into contact with the wafer W. Further, the suction arm 12 may be moved closer to and come into contact with the wafer W while being inclined at a predetermined angle.

Furthermore, although the above has described as to the shape of the arm 12B of the suction arm 12 which is a substantially-Y-like shape as seen in a plane, the present invention is not restricted thereto, and this shape may be changed to various shapes, e.g., an I-like shape or the substantially the same shape as the wafer W in accordance with a size of the wafer W.

Moreover, the virtual flat plane in the present invention is not restricted to the horizontal plane, and it includes a perpendicular plane, an inclined plane and others. Therefore, in a case where a design in which the plate-like object is supported within a perpendicular plane, suction and holding are performed by the above-described principle of the operation even if the plate-like object is inclined with respect to the perpendicular plane due to any error.

Additionally, the plate-like object according to the present invention is not restricted to the semiconductor wafer W, and any other plate-like object, e.g., glass having a sheet attached thereto, a steel plate, a resin plate or the like can be determined as a target.

1. A transfer device comprising a multi-joint type robot which is provided with a plurality of joints each of which is subjected to numerical control,
wherein holding means for holding a plate-like object is provided on a free end side of the robot, and the holding means is provided to be movable in directions of three axes perpendicular to each other, inclined with respect to a virtual flat plane at a predetermined angle and provided to allow contact with the plate-like object.

2. A transfer device comprising a multi-joint type robot which is provided with a plurality of joints each of which is subjected to numerical control,
wherein a suction arm which sucks and holds a semiconductor wafer is provided on a free end side of the robot, and the suction arm is provided to be movable in directions of three axes perpendicular to each other, inclined with respect to a virtual flat plane at a predetermined angle and provided to allow contact with the semiconductor wafer, thereby bringing a sucking portion into contact with the semiconductor wafer.

3. A transfer method for transferring a plate-like object through a transfer device in which a suction arm which sucks and holds the plate-like object is provided on a free end side of a multi-joint type robot to be movable in directions of three axes perpendicular to each other, the multi-joint type robot including a plurality of joints each of which is subjected to numerical control, the transfer method comprising:
inclining the suction arm in accordance with inclination of the plate-like object and bringing a sucking portion of the suction arm into contact with a surface of the plate-like object when the plate-like object is inclined with respect to a virtual flat plane in case of sucking the plate-like object by suction arm; and
subsequently transferring the plate-like object in a state where the plate-like object is sucked by the sucking portion.
